(19) United States
(12) Patent Application Publication
(10) Pub. No.: US 2012/0067402 A1
(43) Pub. Date: Mar. 22, 2012

(54) SOLAR COLLECTION AND LIGHT REGULATION APPARATUS

(75) Inventors: Adrian Kitai, Mississauga (CA); Wei Zhang, Markham (CA)

(73) Assignee: McMaster University, Hamilton, ON (CA)

(21) Appl. No.: 13/255,086

(22) PCT Filed: Mar. 5, 2010
(86) PCT No.: PCT/CA2010/000313

§ 371 Date: Nov. 18, 2011

Related U.S. Application Data
(60) Provisional application No. 61/158,077, filed on Mar. 6, 2009.
(60) Provisional application No. 61/187,740, filed on Jun. 17, 2009.

(51) Int. Cl. H01L 31/052; H01L 31/0216; H01L 31/0232

(52) U.S. Cl. 136/246; 136/259; 136/256

(57) ABSTRACT

A solar window apparatus for collecting solar energy and regulating light transmission is provided in which the solar window comprises a plurality of transparent optical elements adhered to an internal surface of a transparent pane. The optical elements each comprise an externally facing surface and an internally facing light collecting surface with a light collecting element adhered thereto, where the externally facing surface preferably has an area that is larger than that of the light collecting surface. Each optical element further comprises two or more light directing surfaces that internally reflect and concentrate light onto the light collecting elements when light is incident over a first range of angles, and transmit light when light is incident over a second range of angles.

### CROSS-REFERENCE TO RELATED APPLICATIONS

This application claims priority to U.S. Provisional patent application Ser. No. 61/158,077, titled “SOLAR WINDOW MODULE”, filed on Mar. 6, 2009, and U.S. Provisional Patent Application Ser. No. 61/187,740, titled “SOLAR WINDOW MODULE”, filed on Jun. 17, 2009, the entire contents of which are incorporated herein by reference.

### FIELD OF THE INVENTION

The present invention relates to solar collection devices and solar light regulation devices. More particularly, the invention relates to solar windows comprising solar cells.

### BACKGROUND OF THE INVENTION

Solar cells may be incorporated into building windows such that sunlight incident on the window can both generate electrical power and simultaneously provide illumination for the interior of the building. Windows of this type are known in the art and a trade-off exists between the amount of illumination and the amount of electrical power generated. Standard solar windows embed conventional solar cells into the window which provides poor lighting quality in the building as well as only a limited amount of solar energy.

Other solar window designs known in the art have similar limitations. Thin film semitransparent windows only offer approximately 4-5% conversion efficiency. Windows which use silicon wafer-based solar cells with gaps between cells to allow light transmission produce highly non-uniform lighting which is distracting and makes poor task lighting. In addition, these windows only allow a fixed percentage of window illumination through, and this percentage must be fixed despite a wide range of illumination conditions.

US Patent Application No. 20080271776 (Morgan) provides a design in which an array of transparent triangular prisms is mounted on a transparent pane, where one side of each prism comprises a solar cell. This device is designed to maximize the amount of collected direct sunlight, while allowing scattered light at low inclination angles to be viewed. This design unfortunately does not address the need to modulate the amount of direct incident light to accommodate for daily and seasonal variations in solar illumination conditions. Furthermore, the design is limited to vertical windows and is not adapted for use with horizontal windows such as skylights.

What is therefore needed is a design that enables the collection of light onto a solar collector while modulating the direct transmitted sunlight during daily and seasonal variations, in a module adaptable for a wide range of inclinations.

### SUMMARY OF THE INVENTION

Embodiments of the present invention address the aforementioned need by providing a solar window that regulates the transmission of light over a wide range of incident angles by substantially transmitting the incident light over a first range of angles and collecting and concentrating the incident light onto collecting elements over a second range of angles.

Accordingly, in a first aspect of the invention, there is provided a hybrid solar energy collection and light regulation apparatus comprising:

a substantially transparent pane;

a plurality of substantially transparent optical elements adhered to an internal surface of the pane, wherein light directed onto an external surface of the pane is substantially transmitted through the pane and substantially transmitted through an externally facing surface of each optical element;

each optical element further comprising:
an internally facing light collection surface having adhered thereto a light collection element; and
two or more light directing surfaces;

wherein the light directing surfaces are oriented to reflect a portion of the light transmitted through the externally facing surface when the light is incident upon the pane within a first range of angles, and to transmit a portion of the light transmitted through the externally facing surface when the light is incident upon the pane within a second range of angles; and

wherein at least two of the light directing surfaces are located on opposing sides of the each optical element.

In another embodiment, there is provided a light regulation apparatus comprising:

a substantially transparent pane;

a plurality of substantially transparent optical elements adhered to an internal surface of the pane, wherein light directed onto an external surface of the pane is substantially transmitted through the pane and substantially transmitted through an externally facing surface of each optical element;

each optical element further comprising:
an internally facing surface comprising a coating that is at least partially reflective; and
two or more light directing surfaces;

wherein the light directing surfaces are oriented to reflect a portion of the light transmitted through the externally facing surface when the light is incident upon the pane within a first range of angles, and to transmit a portion of the light transmitted through the externally facing surface when the light is incident upon the pane within a second range of angles; and

wherein at least two of the light directing surfaces are located on opposing sides of the each optical element.

In yet another embodiment, there is provided a light regulation apparatus comprising:

a substantially transparent pane;

a plurality of substantially transparent optical elements adhered to an internal surface of the pane, wherein light directed onto an external surface of the pane is substantially transmitted through the pane and substantially transmitted through an externally facing surface of each optical element;

wherein each optical element further comprises two or more light directing surfaces;

wherein the light directing surfaces are oriented to reflect the light transmitted through the externally facing surface when the light is incident upon the pane within a first range of angles, and to transmit the light transmitted through the externally facing surface when the light is incident upon the pane within a second range of angles.

In another embodiment, there is provided a hybrid solar energy collection and light regulation apparatus comprising:

a substantially transparent first pane;

a plurality of lensing elements positioned adjacent to an internal surface of the pane, wherein light directed onto an external surface of the pane is substantially transmitted through the pane and substantially transmitted through the lensing elements;

a second substantially transparent pane having an externally facing surface located approximately at a focal plane of the lensing elements, the externally facing surface supporting a plurality of light collecting elements, wherein each light collecting element is positioned approximately at a focal point of a given lensing element;

wherein a substantial portion of the light transmitted through the lensing elements is collected by the light collection elements when the light is incident upon the first pane within a first range of angles, and wherein a substantial portion of the light transmitted through the lensing elements is transmitted through the second pane when the light is incident upon the first pane within a second range of angles.

A further understanding of the functional and advantageous aspects of the invention can be realized by reference to the following detailed description and drawings.

### BRIEF DESCRIPTION OF THE DRAWINGS

Preferred embodiments of the invention will now be described, by way of example only, with reference to the drawings, in which:

FIG. 1 shows a cross section of a solar window incorporating optical elements for the collection and transmission of light.

FIG. 2 shows a cross section of an optical element comprising a truncated pyramid.

FIG. 3 illustrates an array of interconnected solar cell elements.

FIG. 4 illustrates an optical element having a light collecting material adhered thereto.

FIG. 5 plots the angular dependence of transmitted light through a solar window.

FIG. 6 plots the angular dependence of collected solar power with and without truncated pyramid optical elements.

FIG. 7 shows a cross section of an optical element comprising a prism.

FIG. 8 shows a partial view of a solar cell window incorporating prisms and solar cell elements.

FIG. 9 illustrates an array of interconnected longitudinal solar cell elements.

FIG. 10 shows the results of a ray tracing simulation with an angle of incidence of 0°.

FIG. 11 shows the results of a ray tracing simulation with an angle of incidence of 5°.

FIG. 12 shows the results of a ray tracing simulation with an angle of incidence of 10°.

FIG. 13 shows the results of a ray tracing simulation with an angle of incidence of 15°.

FIG. 14 shows the results of a ray tracing simulation with an angle of incidence of 20°.

FIG. 15 shows the results of a ray tracing simulation with an angle of incidence of 25°.

FIG. 16 shows the results of a ray tracing simulation with an angle of incidence of 30°.

FIG. 17 shows the results of a ray tracing simulation with an angle of incidence of 35°.

FIG. 18 shows the results of a ray tracing simulation with an angle of incidence of 40°.

FIG. 19 shows the results of a ray tracing simulation with an angle of incidence of 45°.

FIG. 20 shows the results of a ray tracing simulation with an angle of incidence of 50°.

FIG. 21 shows the results of a ray tracing simulation with an angle of incidence of 55°.

FIG. 22 shows the results of a ray tracing simulation with an angle of incidence of 60°.

FIG. 23 shows the results of a ray tracing simulation with an angle of incidence of 65°.

FIG. 24 shows the results of a ray tracing simulation with an angle of incidence of 70°.

FIG. 25 shows the results of a ray tracing simulation with an angle of incidence of 75°.

FIG. 26 shows the results of a ray tracing simulation with an angle of incidence of 80°.

FIG. 27 shows the results of a ray tracing simulation with an angle of incidence of 85°.

FIG. 28 shows the fraction of light transmitted as a function of incident angle of the light entering the solar cell window comprising prism optical elements.

FIG. 29 shows the fraction of incident light absorbed by the solar cells as a function of the incident angle of the light entering the solar cell window.

FIG. 30 illustrates a solar window in which lenses are employed as optical elements.

### DETAILED DESCRIPTION OF THE INVENTION

Generally speaking, the systems described herein are directed to solar windows for the collection and regulated transmission of sunlight. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, the illustrated embodiments are directed to solar windows comprising optical elements and solar collecting elements for the collection and regulation of sunlight.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

As used herein, the terms “about” and “approximately, when used in conjunction with ranges of dimensions of particles, compositions of mixtures or other physical properties or characteristics, is meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present invention.

As used herein, the coordinating conjunction “and/or” is meant to be a selection between a logical disjunction and a logical conjunction of the adjacent words, phrases, or clauses. Specifically, the phrase “X and/or Y” is meant to be interpreted as “one or both of X and Y” wherein X and Y are any word, phrase, or clause.

Embodiments of the present invention provide a solar window incorporating both solar collection and light regulation. Such a solar window provides angular dependent regulation of light transmission, thus preventing too much light from being transmitted during direct sun conditions and increasing the fraction of light transmitted during indirect sun conditions, while collecting the unwanted solar energy with a solar collection element such as a solar cell.

A first embodiment is illustrated in FIG. 1, which shows a solar window 10 having a transparent pane 20 that is preferably made of a transparent material such as glass or thermopane glass. Adhered to an internal surface 25 of pane 20 is a plurality of substantially transparent optical elements 30.

Optical elements 30 comprise an externally facing surface 35 and an internally facing surface 40. As shown in the Figure, the externally facing surface preferably has a larger surface area than the internally facing surface. This causes the concentration of incident sunlight onto a light collecting element 70 adhered to the internally facing surface, when the incident sunlight is provided over a first range of angles. The concentration is caused by the reflection of incident rays by two or more lateral light directing surfaces 50 and 55. The optical elements thus increase the amount of light incident on each collection element and decrease the required size of each collection element. This is advantageous since the size of the collection elements may be reduced, while still maintaining efficient solar collection in direct sun conditions (for example, with reduced solar cell material cost). Optical elements 30 are preferably formed from a transparent material such as glass or acrylic, and are preferably bonded directly to pane 20. Direct bonding improves heat transfer and reduces losses from additional Fresnel reflections.

Each light directing surface 50 and 55 reflects incident rays over a specific range of angles determined by the angle of the surface and the index of refraction of the optical element. The rays are preferably reflected by total internal reflection, although the reflectivity may be produced at least in part by coating one or both of the light directing surfaces with a coating that is at least partially reflective. It is to be understood that light directing surfaces 50 and 55 need not be planar surfaces, and may instead comprise curved or multi-faceted surfaces.

Rays 60 and 65 illustrate the case in which sunlight is normally incident on pane 20, where the rays pass through the pane and are totally internally reflected by surfaces 50 and 55 through the light collecting surface 40. This scenario typically corresponds to a direct sun condition would include angles of illumination when there are no clouds, and the sun is at or near mid-day conditions. After passing through the light collecting surface 40 of the optical element, rays 60 and 65 are collected by light collecting surface 70.

Ray 75 illustrates a case in which sunlight is directed onto pane 20 at an oblique angle. This situation may arise when the solar altitude is such that the ray is a direct ray and the sun is not near its peak altitude, or alternatively the ray may originate as a scattered ray. This could also occur as a sunrise or sunset condition. Ray 75 is refracted at by pane 20 and propagates into optical element 30. Upon encountering light directing surface 50, ray 75 is refracted outside of optical element 30 and transmitted by surface 50. Similarly, ray 80 is refracted by pane 20 and transmitted by element 30.

Solar window 10 therefore provides both solar collection and regulated light transmission that varies as a function of the incident angle. Advantageously, and unlike prior art designs, solar window 10 comprises two light directing surfaces 50 and 55 for selectively transmitting or internally reflecting light rays that are incident from both lateral directions. Each light directing surface transmits light rays over a first incident angular range, and internally reflects light rays over a second incident angular range.

In a preferred embodiment, solar window 10 further comprises a second pane 5, which is secured to first pane 20 by member 15. Solar window may therefore comprise a double-pane window that is sealed to protect the optical elements 30 and additionally provides a low heat transfer value. In a preferred embodiment, second pane optically diffuses transmitted light. This is preferable as light transmitted through optical elements 30 will have a spatial intensity variation that may be desirably removed by a diffusing component integrated within solar cell 10. In non-limiting examples, diffusing component (not shown) may be provided on a surface of second pane 20 or integrated within second pane 20.

The light collection element 70 comprises an element adapted for the collection of light and the conversion of solar energy. In a preferred embodiment, light collection element comprises one or more solar cells. The solar cells are preferably mounted directly to the light collecting surface 40 without an air gap to maximize the collected power. In another embodiment, light collection element 70 comprises a light absorbing material, such as a dark material that may be adhered to the light collecting surface.

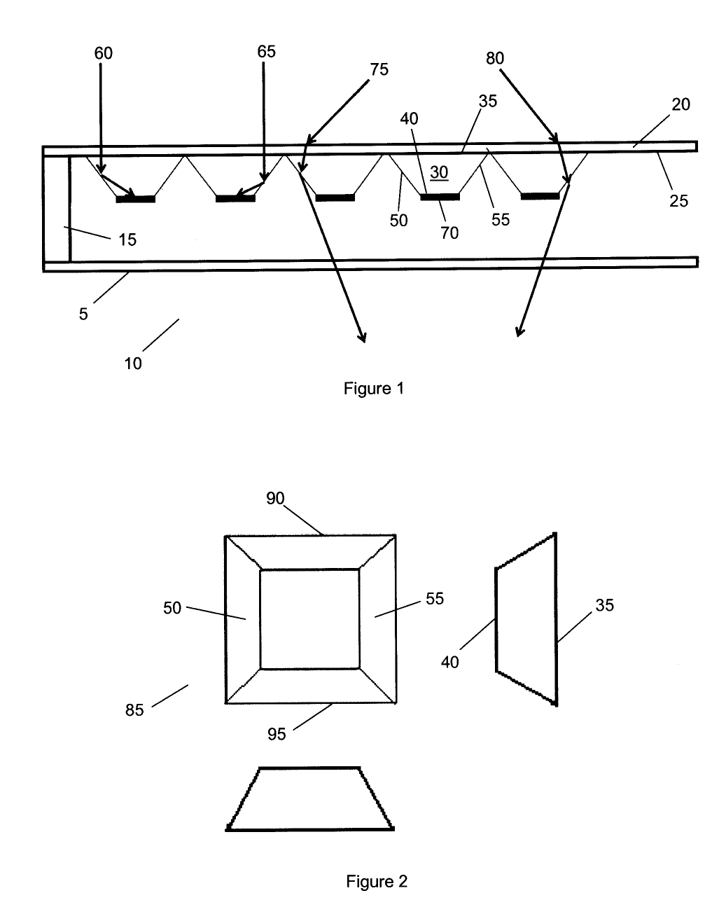

FIG. 2 shows overhead and cross-sectional views of optical element 30 according to one embodiment, in which optical element 30 comprises a truncated square pyramid 85. In this embodiment, externally facing surface 35 comprises the base of the pyramid, and light collecting surface 40 comprises the truncated surface of the pyramid. The pyramid further comprises two additional light directing surfaces 90 and 95. Dual pairs of light directing surfaces are advantageous for modulating transmitted light due to changes in solar altitude and azimuth. The truncated pyramids are preferably arranged in an array, and more preferably arranged in a two-dimensional array. Adjacent pyramids may be in direct contact, or a gap may be provided to allow for increase light transmission.

Those skilled in the art will appreciate that the pyramid shape and geometry may be varied without departing from the scope of the invention, for example, having different base geometries. Additionally, the pyramid base may be additionally truncated at an angle, thereby allowing for light collecting surface 40 to be tilted at an angle relative to pane 20. Such an embodiment may be advantageous as it enables the light collecting surfaces to be tilted to collect an optimal amount of solar energy. For example, in a vertically mounted window, light collecting surfaces of truncated pyramid optical elements could be oriented towards an average seasonal solar inclination.

As noted above, in a preferred embodiment, light collecting elements 40 are solar cells. FIG. 3 illustrates how an array of solar cells may be connected for the extraction of electrical energy. An array of solar cell chips 110 is shown connected to at least two wires 115 and 120. FIG. 3, illustrates an embodiment in which wire 115 is situated below the chips 110, and wire 120 is situated above the chips 110, whereby a voltage is generated between wires 115 and 120. The electrical current and voltage from the chips 110 will contribute to the total current and voltage. As will be apparent to those skilled in the art, solar cell chips 110 may be connected in series, parallel, or a combination thereof. FIG. 3 shows a series-parallel connection of the solar cell chips 110. The wires may be contacted with the solar cell chips by a variety of known methods, such as soldering the wires to the solar cell chips or bonding the wires to the solar cell chips using conductive cement. The wires are preferably made of a highly conductive metal such as silver, copper or aluminum, and the wires are preferably sufficiently rigid to be self-supporting between the solar cell chips. In an embodiment involving two glass panes (as discussed above), the electrical wiring may be externally routed through the window support by suitable electrical connections that retain the seal for the gap between the inner and outer glass plates.

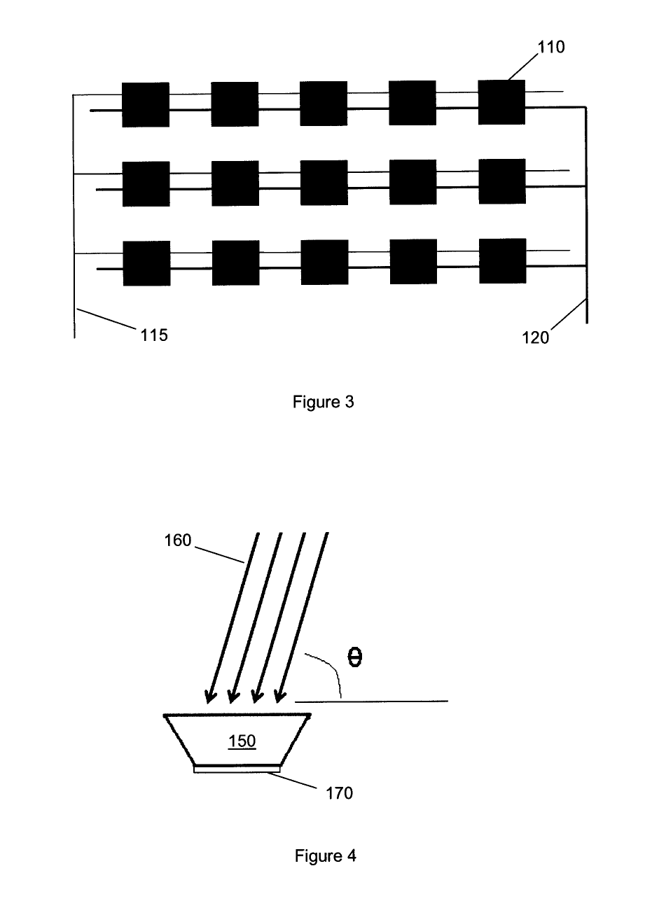

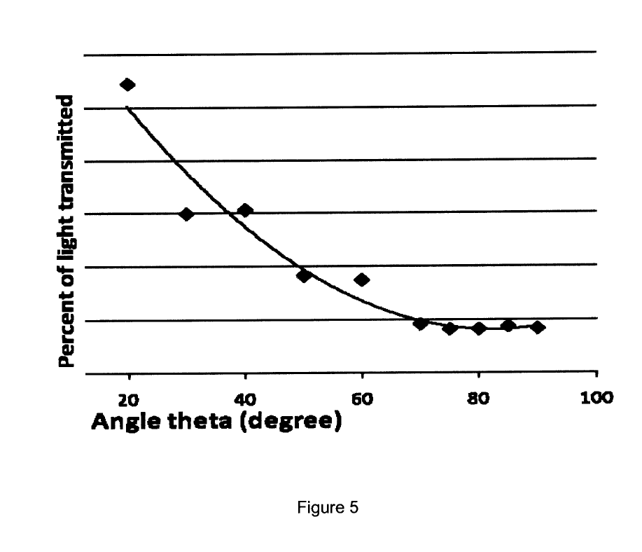

In a non-limiting example, optical elements 40 were obtained by cutting AFG Solite 5/32″ thick solar glass to form a truncated pyramid 150 as shown in FIG. 4. The light beam 160 was incident on the larger surface of the truncated pyramid 150 as shown in FIG. 5. The small surface of the truncated pyramid was covered by a light absorbing film 170.

The performance of the truncated pyramid was determined by measuring the percentage of light transmitted through the truncated pyramid as a function of the angle θ of the light incident 160 on the truncated pyramid 150. The result is shown in FIG. 5. Note that when θ=90°, which is an example of a direct sun condition, the percentage of light transmitted is about 4% and when theta is 20°, which is an example of an indirect sun condition, the percentage of light transmitted has increased to over 25%.

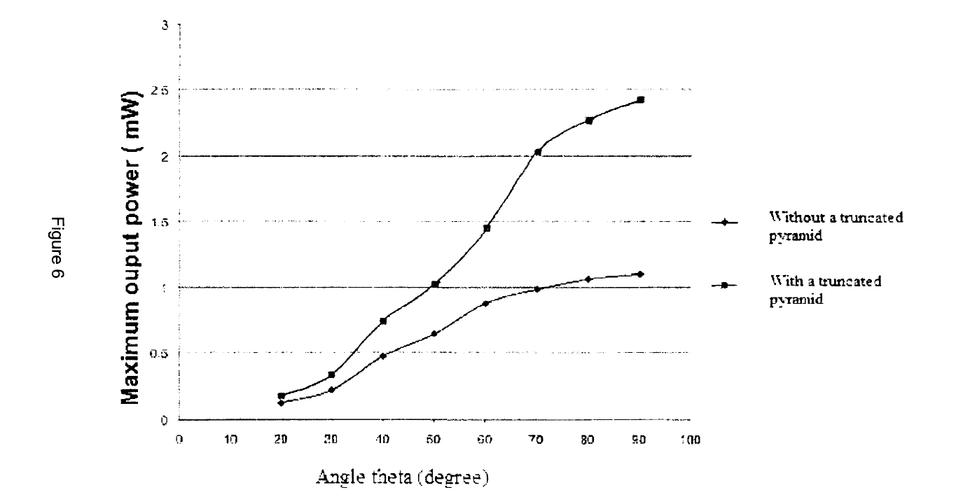

In addition, measurements were made of electrical power available from the same truncated pyramid as shown in FIG. 4 when a silicon solar cell chip is substituted for the light absorbing film. This data was measured as a function of θ as shown in FIG. 6. It is noteworthy that power can be generated from a wide range of angles. If the same solar cell chip is illuminated with the same light source but without the truncated pyramid, then a much lower power is measured, as also shown in FIG. 6.

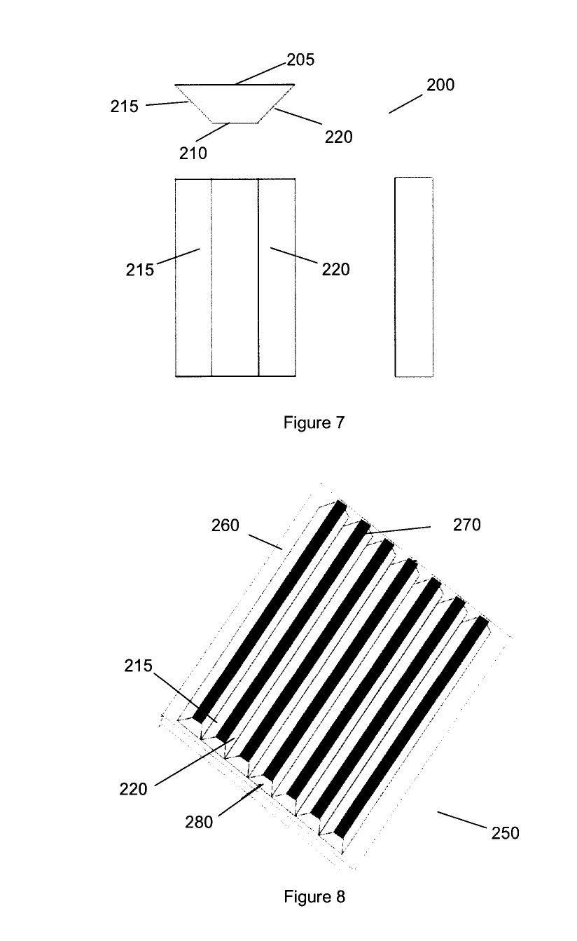

FIGS. 7 and 8 illustrate a preferred embodiment in which optical element 30 is a longitudinal transparent structure that is preferably a prism. Shown in FIG. 7 are the various surfaces of the prism, including externally facing surface 205, light collecting surface 210, and light directing surfaces 215 and 220. Accordingly, prism 200 has a transverse cross-section as shown in FIG. 1.

Preferably, the solar window comprises a one-dimensional array of longitudinal prisms, as shown in FIG. 8. Solar window 250 comprises transparent pane 260 and a plurality of longitudinally oriented prism. Shown in the Figure are light collection elements 270 adhered to light collecting surfaces of the prisms, and light directing surfaces 215 and 220. While adjacent prisms are shown in mutual contact, it is to be understood that a lateral gap may be provided to increase the transmission of light through the structure. Furthermore, one or both ends 280 of each prism may be cut at an angle relative to a plane orthogonal to a longitudinal axis of the prism.

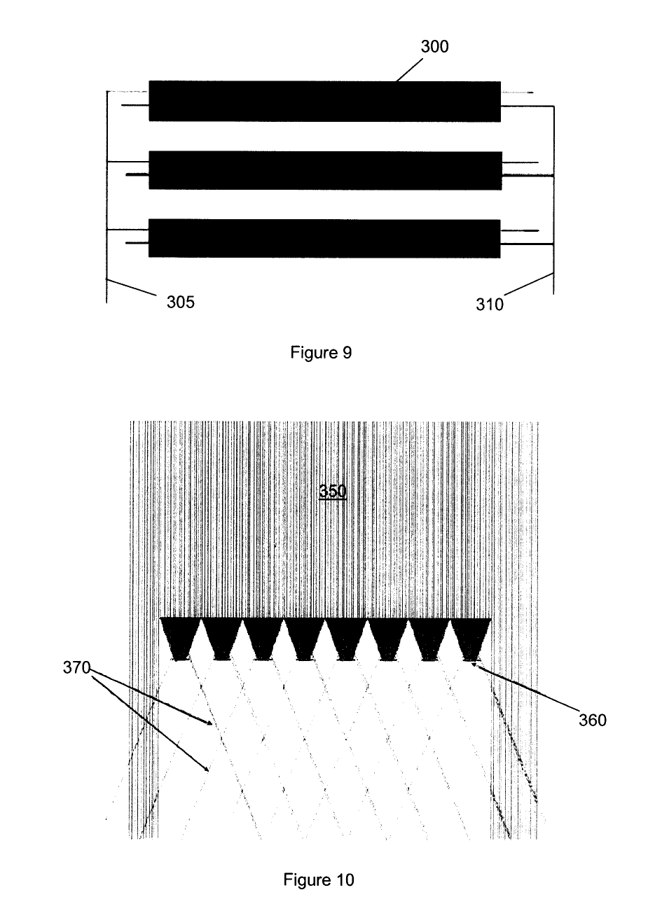

As discussed above, the optical collection elements 270 adhered to the light collection surfaces 210 are preferably solar cells. FIG. 9 shows the manner in which solar cells may be connected for the embodiment shown in FIG. 8. An array of solar cell elements 300 is shown, where each solar element is connected to at least two wires 305 and 310. In the Figure, wire 305 is situated below the solar cells 300, and wire 310 is situated above the solar cells 300. Accordingly, a voltage is generated between wires 305 and 310. The electrical current and voltage from the elements 300 will contribute to the total current and voltage.

FIG. 9 shows a parallel connection of the solar cell elements, although it will be clear to those skilled in the art that the solar cell elements could also be connected in series or in a series/parallel arrangement. As noted above, the wires may be connected to the solar cells using one of many means, including soldering the wires to the solar cell elements using solder or bonding the wires to the solar cell elements using conductive cement. The wires are preferable made of a highly conductive metal such as silver, copper or aluminum. FIG. 9 shows only one solar cell element for each long solar cell length, however two or more suitably connected solar cell elements could be used to increase the effective length of the solar cells. In an embodiment involving two panes (as discussed above), the electrical wiring may be externally routed through the window support by suitable electrical connections that retain the seal for the gap between the inner and outer glass plates.

Although the optical elements shown in FIGS. 7 and 8 are isosceles trapezoidal prisms, it is to be understood that the prisms can take on a wide variety of geometries without departing from the scope of the invention. The prisms preferably include at least four lateral sizes, with a first side comprising the externally facing surface, a second side comprising the light collecting surface, and at least two additional light directing surfaces, where the light directing surfaces are preferably located on either side of the prism. The prism is preferably a quadrilateral prism, and more preferably, a trapezoidal prism. The light directing sides of the prism need not be planar surfaces, and may instead comprise curved or multi-faceted surfaces.

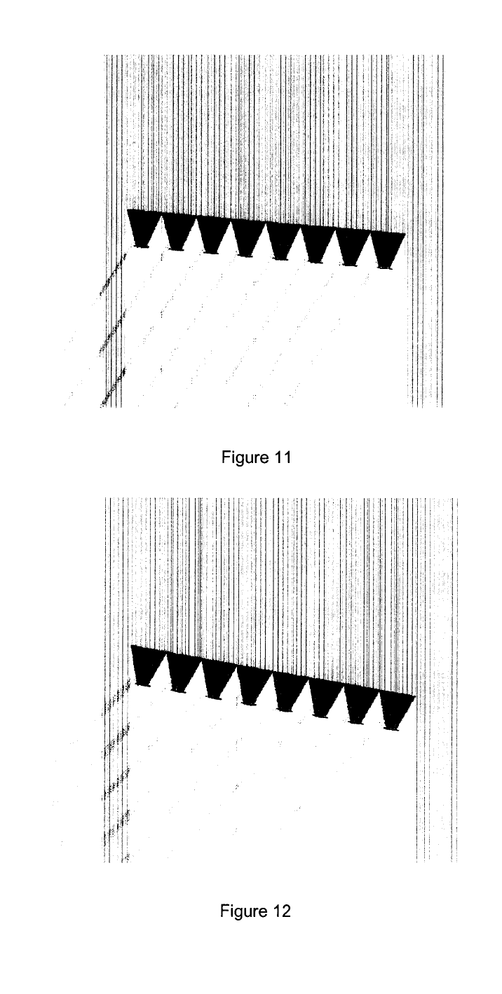

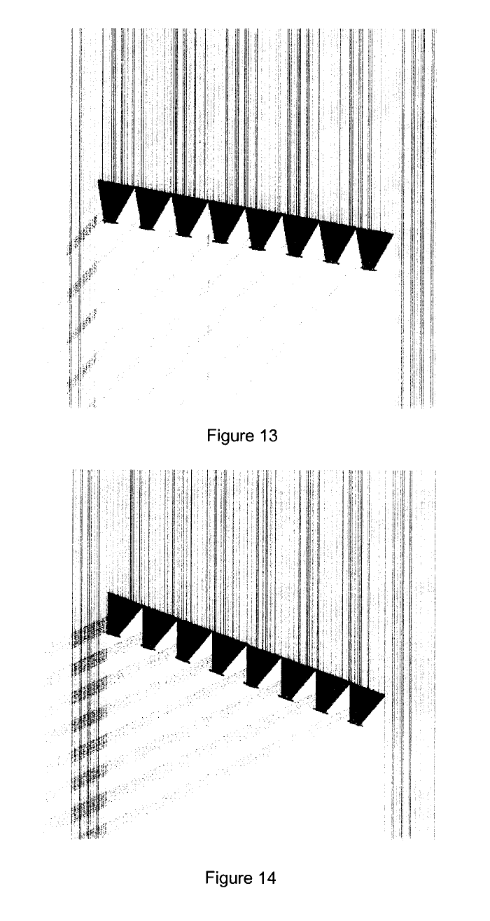

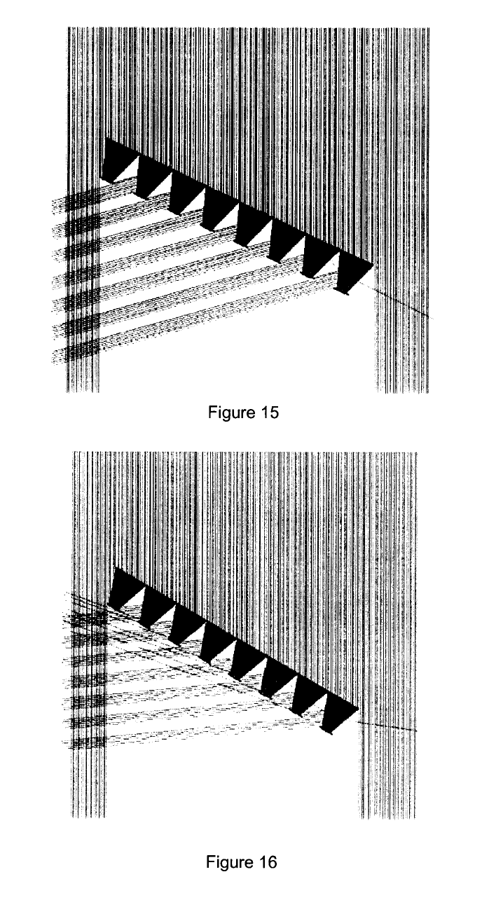

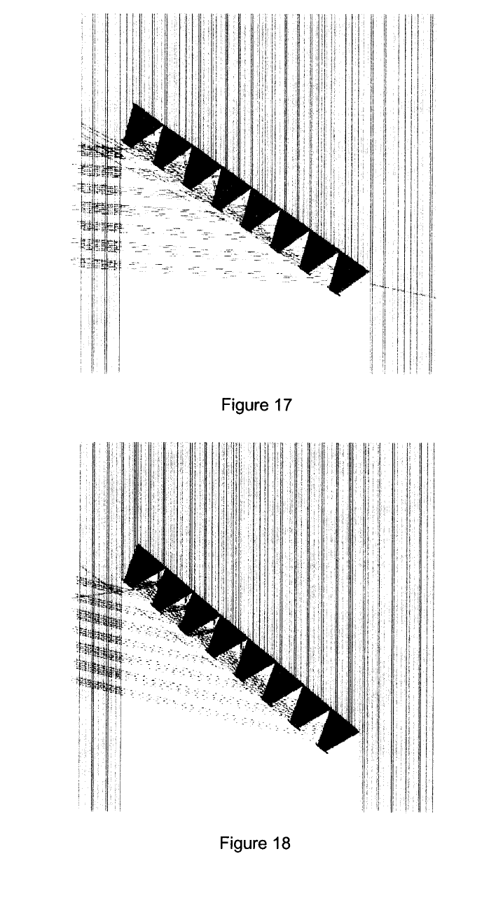

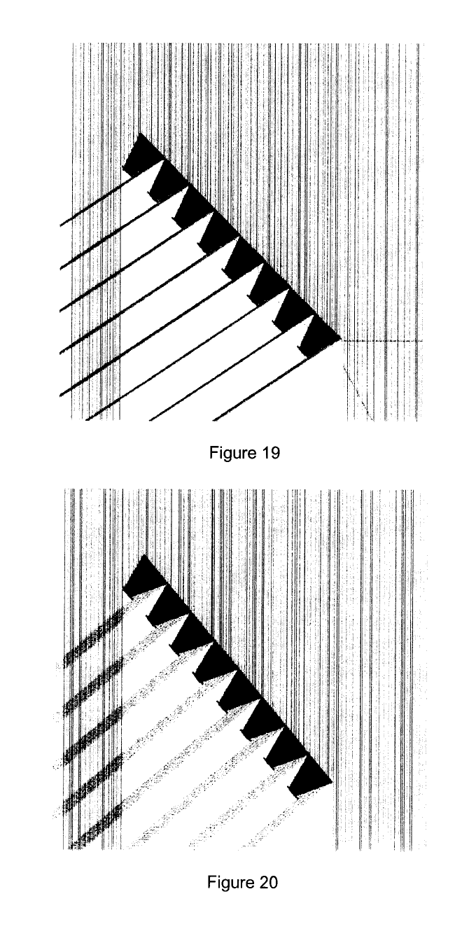

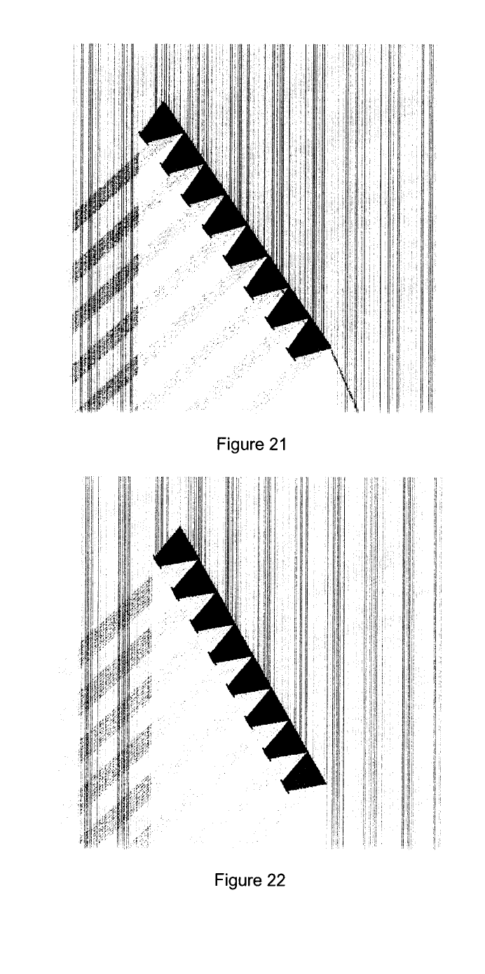

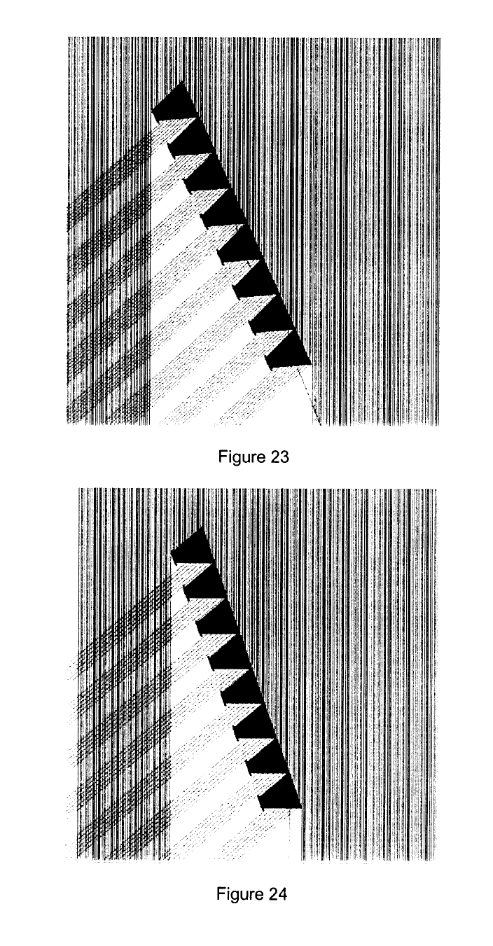

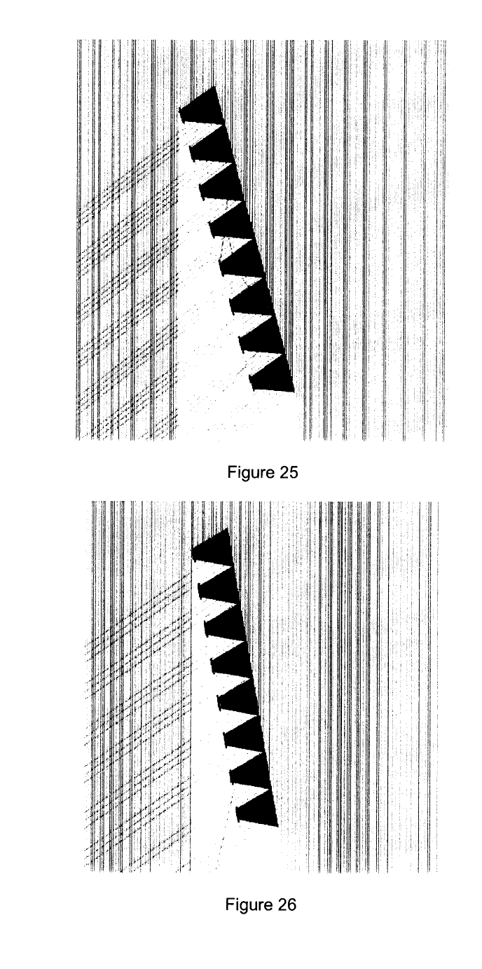

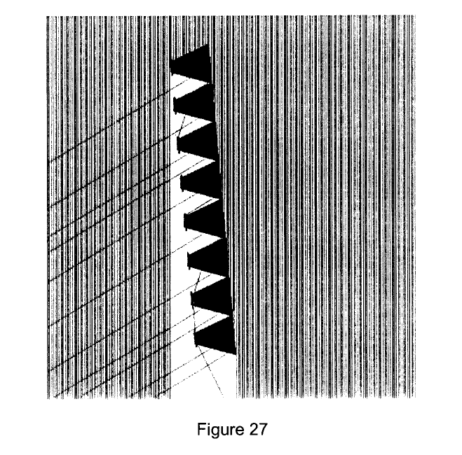

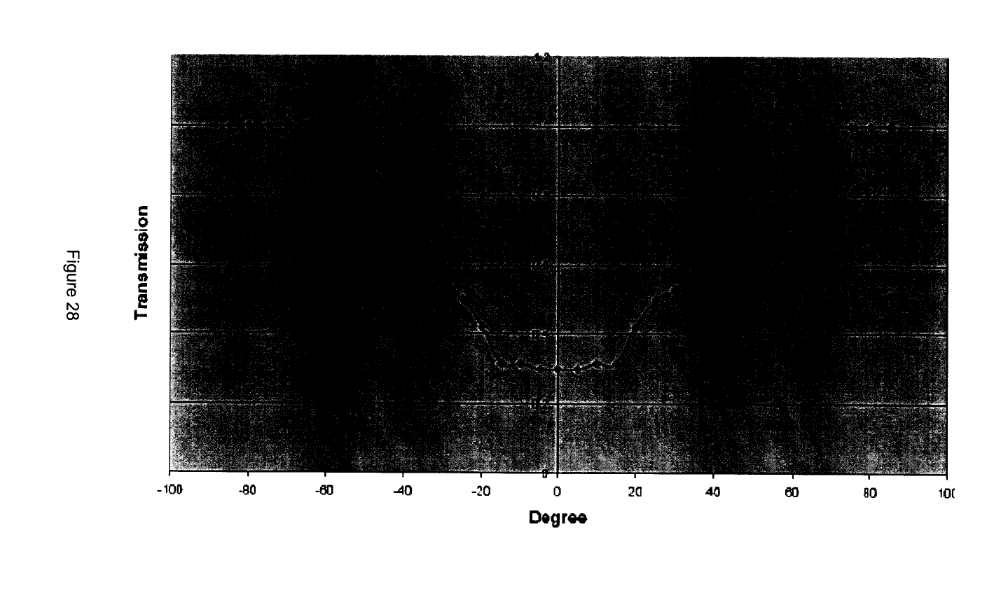

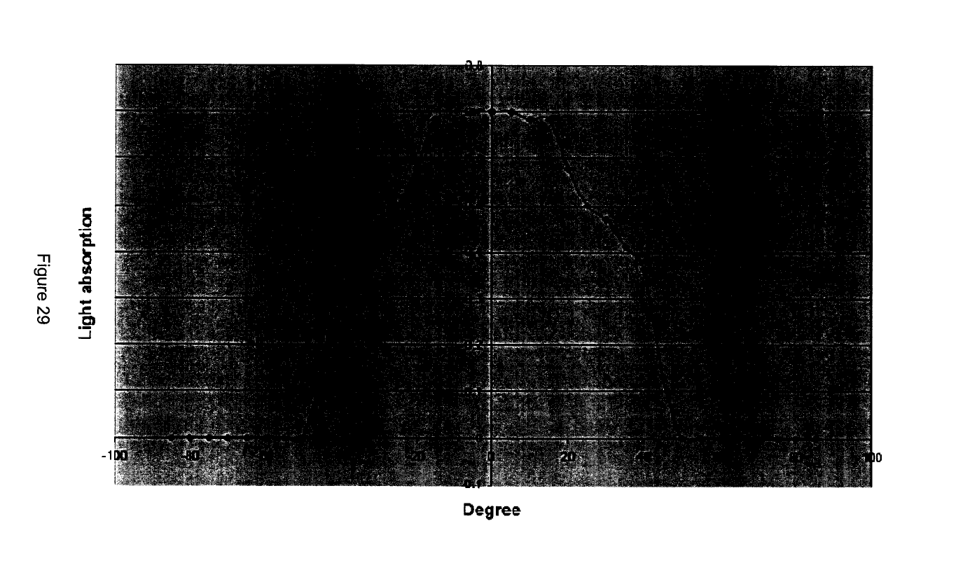

FIGS. 10-27 provide results from a simulation involving the non-limiting embodiment shown in FIG. 8. The collection and transmission of sunlight incident on the solar window was simulated through optical ray tracing software (Optic Lab). The optical path of the incident light beam at various incident angles is analyzed over three modes. In a first mode, the incident angle ranges from 0 degrees to 25°, and the light path is illustrated in FIGS. 10 to 15, where the incident angle is increased from 0 to 25° in steps of 5°. In FIG. 10, the sunlight entering the window is shown at 350, and most of the sunlight reaches the solar cell elements 360. The light being transmitted through the window is shown at 370. For simplicity, the first and second panes 20 and 5 are not shown in the Figures. The incident angle is measured as the angle between the incident light beam and the normal to the solar window surface. The modeling is two dimensional.

In a second mode, the incident angle ranges from 30° to 40° degrees and the light path is illustrated in FIGS. 16 to 18. In this intermediate mode, a portion of the light transmitted into the optical elements is directed to the solar cells, and another portion is refracted and transmitted by the light directing surfaces. In a third mode, the incident angle ranges from 45° to 85°, and the light path is illustrated in FIGS. 19 to 27. In this transmissive mode, most of the light transmitted into the optical elements is refracted and transmitted by the light directing surfaces. It is noted that in all three modes, light is directed either to the solar cells or through the window.

FIG. 28 shows the calculated fraction of the incident light that is transmitted through the solar window as a function of the angle of light incidence, and FIG. 29 shows the fraction of the incident light that is collected by the solar cells as a function of the angle of light incidence. At 0 degrees, 30% of the light is transmitted through the window and 70% of the light reaches the solar cells. As the incident angle is increased, the percentage of transmitted light monotonically increases, until full transmission is achieved for angles in excess of approximately 4 degrees (not including losses due to Fresnel reflections).

It should be noted that the computer modeling does not take into account optical effects such as absorption losses in the optical materials, and surface reflections. In addition, the influence of the inner glass which could be a diffusing glass sheet has not been included, and three dimensional modeling rather than the two dimensional used would be needed to obtain more precise results.

FIGS. 28 and 29 highlight the unique functionality of the solar windows according to various embodiments of the invention, where the transmitted light is bi-modally modulated on either side of the minimum transmission direction. This feature is achieved by the incorporation of at least two light directing surfaces in the optical element. Each light directing surface provides transmission for a range of angles on either side of the angle of normal incidence.

This feature provides a significant benefit when a solar window according to an embodiment of the invention is oriented in selected geometries. If the solar window is oriented such that (a) the optical elements can receive direct sunlight and (b) the optical elements have their longitudinal axis directed approximately within a plane that includes a single line of longitude, then the daily time-dependent transmission of sunlight through the solar window has a trend that is opposite to that of the intensity of sunlight directed onto the window. This has the benefit of reducing the amount of light transmitted during peak hours of sunlight, and the reduced light is advantageously received by the collection elements for solar energy conversion. It is important to note that this benefit can be obtained for solar windows installed in a wide range of configurations, including both horizontal windows, such as skylights, and vertical windows.

An additional benefit is also obtained when the solar window is further oriented to account for seasonal changes in solar altitude. If the solar window is oriented such that the minimum transmission occurs during the summer season, then an increase in transmission will be obtained during the winter season. This can be beneficial in regulating the amount of light transmitted into a building to optimize the internally transmitted heat during the winter and minimize the amount of internally transmitted heat during the summer.

In another embodiment of the invention, the solar window apparatus as described in various embodiments herein may comprise a retrofit kit that includes fasteners such as mounting screws, suction devices, or other hardware for securing the pane 20 to an internal surface of an existing window.

Referring again to FIG. 1, light collecting elements 70 are mounted along with the optical elements 30 to transparent pane 20 and do not contact second pane 5. This may be advantageous in warm climates where air conditioning is required to maintain indoor air temperature since the second pane 5 does not directly contact the light collecting elements, and therefore less air conditioning would be required. For example, since solar cells heat up in sunlight, the temperature rise of the inner glass in warm climates will be reduced by the insulation provided by the space between panes 5 and 20.

It should also be realized, however, that the solar cells will be heated by the sun, which will decrease the solar cell performance for silicon solar cells. Accordingly, in embodiments in which light is collected by a light collection element adhered to each optical element, a means of heat transfer is preferably included for conducting heat away from the light collection elements. Such a heat transfer means may be implemented for ensuring that solar cells are operating efficiently and/or extracting useful thermal energy collected by the solar window (for example, if light collection element is a light absorbing material). In one embodiment, the heat transfer means may comprise a heat sink in thermal communication with the light collecting elements. In a non-limiting example, the heat sink may comprise a conductive rod provided below each longitudinal optical element shown in FIG. 8. Alternatively, the heat sink may comprise a liquid conduit for flowing a liquid, where the conduit provides direct or indirect thermal communication between the light collecting elements and the fluid. Preferably, liquid is flowed through the conduit using a flow means such as a pump. In selected embodiments in which the conduit is exposed to incident light, the conduit and working liquid are preferably substantially transparent.

In another embodiment of the invention, light directing surfaces may further comprise a partially reflective material for increasing the surface reflectivity. Additionally, a reflective material may be substituted for the light collecting element to provide a solar window that regulates transmission without collecting solar energy. The reflective material substituted for the light collecting element may be partially or fully reflective.

In yet another embodiment, the solar window may provide light regulation and without light collection, where the optical element comprises a prism having at least two light directing surfaces, whereby the light collecting element and light collecting surface are absent. Light incident on the solar window over a first range of angles is externally reflected through total internal reflection and light incident on the window from a second range of angles is transmitted. In a preferred embodiment, the prism comprises a triangular prism for light regulation by total internal reflection.

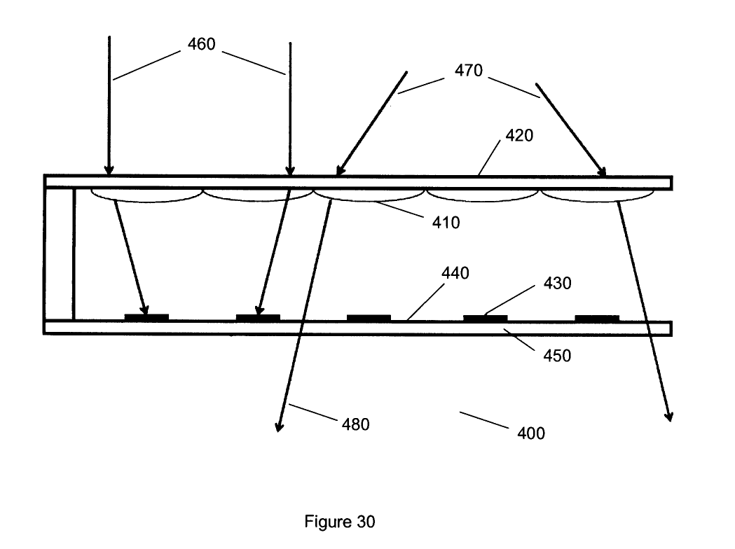

FIG. 30 provides an alternative embodiment of a solar window 400 in which the optical elements of FIG. 1 are replaced with lenses 410. Lenses preferably comprise a flat surface for ease of mounting to external pane 420. Preferred lenses include, but are not limited to, plano-convex lenses, and diffractive elements such as Fresnel lenses. Light collecting elements 430 are supported on externally-facing surface 440 of internal pane 450. Preferably, internal surface 450 is positioned near a focal plane of lenses 410, and each light collecting element 430 is positioned at a focal point of a given lens 410. Accordingly, light incident from a first range of angles 460 is directed by lenses 410 onto light collecting elements 430, and light incident from a second range of angles 470 is transmitted though internal pane 450. Preferably, internal pane 450 diffuses transmitted light 480. Such an embodiment may be useful in cold climates, whereby light collection elements 430 mounted on internal pane 450 provide a temperature rise that could also provide heat to internal pane 450.

It is to be understood that the geometry and location of the optical elements and their relative location on the pane may preferably be selected to account for the thermal conditions including the solar cell temperature and window heat transfer, and to obtain a desired optical performance including window light transmission as a function of light angle, and on the electrical performance required. For example, optical elements may be spaced apart with a gap therebetween to allow for increase light transmission. Those skilled in the art of solar cells and window design will readily appreciate that design variants involving the aforementioned principles and examples are within the scope of the present embodiments.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. A hybrid solar energy collection and light regulation apparatus comprising:
a substantially transparent pane;
a plurality of substantially transparent optical elements adhered to an internal surface of said pane, wherein light directed onto an external surface of said pane is substantially transmitted through said pane and substantially transmitted through an externally facing surface of each optical element;
each optical element further comprising:
an internally facing light collection surface having adhered thereto a light collection element; and
two or more light directing surfaces;
wherein said light directing surfaces are oriented to reflect a portion of said light transmitted through said externally facing surface when said light is incident upon said pane within a first range of angles, and to transmit a portion of said light transmitted through said externally facing surface when said light is incident upon said pane within a second range of angles; and
wherein at least two of said light directing surfaces are located on opposing sides of said each optical element.

2. The apparatus according to claim 1 further comprising an internal optical diffusing component.

3. The apparatus according to claim 1 wherein said substantially transparent pane is an external pane, said apparatus further comprising a substantially transparent internal pane, said external and internal panes forming a double-pane window wherein said optical elements are located between said internal and external panes.

4. The apparatus according to claim 3 wherein said internal pane is an optically diffusing pane.

5. The apparatus according to claim 1 wherein heat absorbed by said light collection elements is substantially thermally conducted to said pane.

6. The apparatus according to claim 1 further comprising a heat sink means in thermal communication with one or more of said light collection elements.

7. The apparatus according to claim 6 wherein said heat sink means comprises a liquid conduit thermally contacting one or more of said light collection elements.

8. The apparatus according to claim 7 further comprising a flow means for flowing said liquid through said conduit.

9. The apparatus according to claim 7 wherein said conduit is substantially transparent.

10. The apparatus according to claim 1 wherein said optical elements are adhered to said internal surface of said pane without an air gap therebetween.

11. The apparatus according to claim 1 wherein said optical elements are provided in an array.

12. The apparatus according to claim 1 wherein said externally facing surface is larger in area than said light collecting surface.

13. The apparatus according to claim 12 wherein each optical element comprises a prism, wherein said externally facing surface, said light collecting surface, and said light directing surfaces are sides of said prism, said sides having an axis parallel to a longitudinal axis of said prism.

14. The apparatus according to claim 13 wherein said prisms are arranged in a one-dimensional array.

15. The apparatus according to claim 13 wherein one or both ends of said prism are cut at an angle relative to a plane orthogonal to a longitudinal axis of said prism.

16. The apparatus according to claim 15 wherein said prism is a quadrilateral prism.

17. The apparatus according to claim 16 wherein said prism comprises a trapezoidal cross-section.

18. The apparatus according to claim 12 wherein said optical element comprises a truncated pyramid, wherein said light collecting surface comprises a truncated surface of said pyramid.

19. The apparatus according to claim 18 wherein a base of said pyramid is additionally truncated at an oblique angle, wherein said light collecting surface is oriented at an angle relative to said a substantially transparent pane.

20. The apparatus according to claim 18 wherein said optical elements comprise a two-dimensional array.

21. The apparatus according to claim 1 wherein one or more of said light directing surfaces comprise a coating that is partially reflective.

22. The apparatus according to claim 13, said apparatus mounted in a vertical orientation wherein said longitudinal axis is oriented in a substantially vertical direction, wherein sunlight is partially transmitted by a first light directing surface during a first time duration during a day, and is partially transmitted by second light directing surface during a second time duration during said day.

23. The apparatus according to claim 1, wherein each light collection element comprises a solar cell, said apparatus further comprising connection means for electrically connecting said solar cells.

24. The apparatus according to claim 23 wherein each solar cell is connected to each light collection surface without an air gap therebetween.

25. The apparatus according to claim 1, wherein said light collecting element comprises an absorbing medium.

26. The apparatus according to claim 25 wherein said absorbing medium comprises a light absorbing coating applied to said light collecting surface.

27. The apparatus according to claim 1 further comprising a retrofitting kit, said kit comprising fastening means for securing said substantially transparent pane relative to an internal surface of a window.

28. A window retrofitted with an apparatus according to claim 1.

29. A skylight comprising an apparatus according to claim 1.

30. A light regulation apparatus comprising:
a substantially transparent pane;
a plurality of substantially transparent optical elements adhered to an internal surface of said pane, wherein light directed onto an external surface of said pane is substantially transmitted through said pane and substantially transmitted through an externally facing surface of each optical element;
each optical element further comprising:
an internally facing surface comprising a coating that is at least partially reflective; and
two or more light directing surfaces;
wherein said light directing surfaces are oriented to reflect a portion of said light transmitted through said externally facing surface when said light is incident upon said pane within a first range of angles, and to transmit a portion of said light transmitted through said externally facing surface when said light is incident upon said pane within a second range of angles; and
wherein at least two of said light directing surfaces are located on opposing sides of said each optical element.

31. The apparatus according to claim 30 wherein one or more of said two or more light directing surfaces comprise an additional coating that is at partially reflective.

32. A light regulation apparatus comprising:
a substantially transparent pane;
a plurality of substantially transparent optical elements adhered to an internal surface of said pane, wherein light directed onto an external surface of said pane is substantially transmitted through said pane and substantially transmitted through an externally facing surface of each optical element;
wherein each optical element further comprises two or more light directing surfaces;
wherein said light directing surfaces are oriented to reflect said light transmitted through said externally facing surface when said light is incident upon said pane within a first range of angles, and to transmit said light transmitted through said externally facing surface when said light is incident upon said pane within a second range of angles.

33. The apparatus according to claim 32 further comprising an internal optical diffusing component.

34. The apparatus according to claim 32 wherein said substantially transparent pane is an external pane, said apparatus further comprising an internal substantially transparent pane, said external and internal panes forming a double-pane window wherein said optical elements are located between said external and internal panes.

35. The apparatus according to claim 34 wherein said internal pane is an optically diffusing pane.

36. The apparatus according to claim 32 wherein said optical elements are adhered to said internal surface of said pane without an air gap.

37. The apparatus according to claim 32 wherein said optical elements are provided in an array.

38. The apparatus according to claim 32 wherein each optical element comprises a prism, wherein said externally facing surface and said light directing surfaces are sides of said prism, said sides having an axis parallel to a longitudinal axis of said prism.

39. The apparatus according to claim 38 wherein said prisms are arranged in a one-dimensional array.

40. The apparatus according to claim 38 wherein one or both ends of said prism are cut at an angle relative to a plane orthogonal to a longitudinal axis of said prism.

41. The apparatus according to claim 40 wherein said prism is a triangular prism.

42. The apparatus according to claim 32 wherein one or more of said light directing surfaces comprise a coating that is at least partially reflective.

43. The apparatus according to claim 38, said apparatus mounted in a vertical orientation wherein said longitudinal axis is oriented in a substantially vertical direction, wherein sunlight is partially transmitted by a first light directing surface during time duration during a day, and is partially transmitted by second light directing surface during a second time duration during said day.

44. A skylight comprising an apparatus according to claim 32.

45. A hybrid solar energy collection and light regulation apparatus comprising:
a substantially transparent first pane;
a plurality of lensing elements positioned adjacent to an internal surface of said pane, wherein light directed onto an external surface of said pane is substantially transmitted through said pane and substantially transmitted through said lensing elements;
a second substantially transparent pane having an externally facing surface located approximately at a focal plane of said lensing elements, said externally facing surface supporting a plurality of light collecting elements, wherein each light collecting element is positioned approximately at a focal point of a given lensing element;
wherein a substantial portion of said light transmitted through said lensing elements is collected by said light collection elements when said light is incident upon said first pane within a first range of angles, and wherein a substantial portion of said light transmitted through said lensing elements is transmitted through said second pane when said light is incident upon said first pane within a second range of angles.

46. The apparatus according to claim 45 wherein said lensing elements are cylindrical lenses plano-convex lenses.

47. The apparatus according to claim 45 wherein said lensing elements are cylindrical Fresnel lenses.

48. The apparatus according to claim 45 wherein said lensing elements are adhered to said first pane without an air gap therebetween.

49. The apparatus according to claim 45 wherein said second pane is an optically diffusing pane.
